(19) United States
(12) Patent Application Publication
(10) Pub. No.: US 2025/0372440 A1
(43) Pub. Date: Dec. 4, 2025

(54) METHOD FOR FORMING FLASH MEMORY

(71) Applicant: Winbond Electronics Corp., Taichung City (TW)

(72) Inventors: Chih-Jung NI, Taichung City (TW); Cheng-Pu HO, Taichung City (TW); Ying-Ju CHEN, Taichung City (TW); Ting-Wei YU, Taichung City (TW)

(21) Appl. No.: 19/207,591

(22) Filed: May 14, 2025

(30) Foreign Application Priority Data
May 31, 2024 (TW) 113120232

(51) Int. Cl. H01L 21/762; H10B 41/30; H10D 64/27

(52) U.S. Cl. CPC H01L 21/7621; H10B 41/30; H10D 64/513

(57) ABSTRACT

A method for forming a flash memory is provided. The method includes forming a strip pattern, which includes an active region, a pad oxide layer, a protection layer, an etch stop layer, and a mask layer sequentially stacked on a semiconductor substrate. The sidewalls of the strip pattern are exposed from first trenches. The method also includes forming an isolation structure in the first trench, etching the mask layer of the strip pattern to form the second trench until the etch stop layer is exposed, performing an oxidation process on the active region, removing the etch stop layer, removing the protection layer, and forming a first gate electrode layer in the second trench.

### CROSS REFERENCE TO RELATED APPLICATIONS

This application claims the benefit of Taiwan Patent Application No. 113120232 filed on May 31, 2024, entitled “FLASH MEMORY AND METHOD FOR FORMING THE SAME” which is hereby incorporated herein by reference.

### BACKGROUND

### Field of the Disclosure

The present disclosure relates in general to a flash memory structure and a method for forming the same, and in particular, it relates to a flash memory with a tunnel oxide layer and a method for forming the same.

### Description of the Related Art

In order to increase the component density within flash memory devices and enhance their overall performance, current techniques for manufacturing flash memory devices are continually trending towards miniaturization of components through a reduction in their overall sizes. Therefore, improving the methods of manufacturing flash memory devices is a crucial challenge that must be addressed.

### SUMMARY

The method for forming a flash memory includes forming a strip pattern, which includes an active region, a pad oxide layer, a protection layer, an etch stop layer, and a mask layer sequentially stacked on a semiconductor substrate. The sidewalls of the strip pattern are exposed from first trenches. The method also includes forming an isolation structure in the first trench, etching the mask layer of the strip pattern to form the second trench until the etch stop layer is exposed, performing an oxidation process on the active region, removing the etch stop layer, removing the protection layer, and forming a first gate electrode layer in the second trench.

The method for forming a flash memory includes forming a strip pattern over a semiconductor substrate. The strip pattern includes an active region, a pad oxide layer over the active region, and a mask layer over the pad oxide layer. The method further includes forming an isolation structure surrounding the strip pattern, removing the mask layer of the strip pattern to form a first trench, and performing a rapid thermal oxidation process. The rapid thermal oxidation process includes introducing an oxygen-containing gas into the first trench, diffusing the oxygen-containing gas through the isolation structure to the active region, and oxidizing a portion of the active region. The method further includes forming a first gate electrode layer in the first trench, recessing the isolation structure, and forming an inter-gate dielectric structure and a second gate electrode layer over the isolation structure to surround the first gate electrode layer.

### BRIEF DESCRIPTION OF THE DRAWINGS

In accordance with some embodiments of the present disclosure, it may be further understood by reading the subsequent detailed description and examples with references made to the accompanying drawings, wherein:

FIGS. 1 through 12 are cross-sectional views illustrating the formation of a flash memory at various intermediate stages, in accordance with some embodiments.

FIGS. 4-1, 6-1 and 8-1 respectively illustrate some details of the profile of the pad oxide layer in FIGS. 4, 6 and 8.

FIG. 10-1 illustrates some details of the profile of the tunnel oxide layer in FIG. 10.

### DETAILED DESCRIPTION

In the manufacturing technology of flash memory devices, the profile of the pad oxide on the active region needs to be well controlled, as it affects the profile of the tunnel oxide, which in turn impacts the program/erase efficiency and/or data retention of the flash memory device. For example, if the tunnel oxide is too thin at the corners of the active region, it may cause low-temperature data retention (LTDR) issues. As flash memory devices continue to scale down, controlling the profile of the pad oxide faces greater challenges. Accordingly, the embodiments of the present disclosure provide a flash memory device with pad oxide and tunnel oxide, both of which have desired profiles and a method for forming the same.

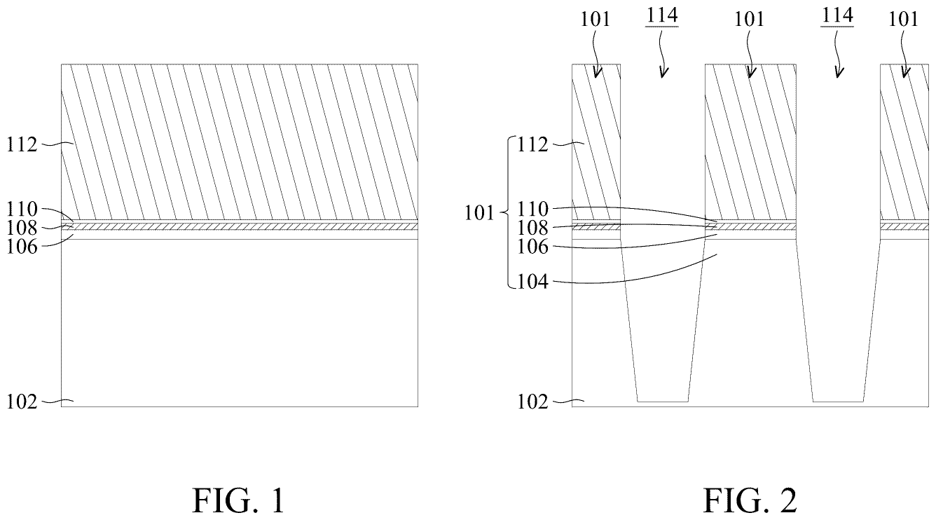

Referring to FIG. 1, a semiconductor substrate 102 is provided. In some embodiments, the semiconductor substrate 102 is an elemental semiconductor substrate, such as a silicon substrate or a germanium substrate, or a compound semiconductor substrate, such as a silicon carbide substrate or a gallium arsenide substrate. In some embodiments, the semiconductor substrate 102 may be a semiconductor-on-insulator (SOI) substrate.

A pad oxide layer 106, a protection layer 108, an etch stop layer 110, and a mask layer 112 are sequentially formed over the semiconductor substrate 102. In some embodiments, the pad oxide layer 106 is a silicon oxide layer, which may be formed using thermal oxidation, in-situ steam generation (ISSG), chemical vapor deposition (CVD), or atomic layer deposition (ALD). The protection layer 108 is a silicon nitride layer, which may be formed using CVD or ALD. The protection layer 108 has a different etch selectivity with respect to the pad oxide layer 106, which may help protect the pad oxide layer 106 from loss during subsequent etching processes. Additionally, during a subsequent rapid oxidation process, the protection layer 108 can protect the active regions 104 from direct and rapid oxidation.

The etch stop layer 110 is a silicon oxide and/or silicon oxynitride which is formed over the protection layer 108 using in-situ steam generation. Specifically, the nitrogen concentration in the etch stop layer 110 decreases from the bottom surface toward the top surface of the etch stop layer 110. In other words, the etch stop layer 110 is silicon oxynitride near its bottom surface and silicon oxide near its top surface. The mask layer 112 is a silicon nitride layer, which may be formed using CVD or ALD. The etch stop layer 110 has a different etch selectivity with respect to the mask layer 112 and the protection layer 108.

Referring to FIG. 2, a patterning process is performed on the semiconductor structure of FIG. 1 to form multiple trenches 114. Multiple strip patterns 101 protrude from between the trenches 114. The patterning process may include forming a patterned photoresist layer (not shown) over the mask layer 112 using a lithography process, followed by etching the semiconductor structure to transfer the patterns of the patterned photoresist layer into the semiconductor substrate 102. The portions of the semiconductor substrate 102 protruding from between the trenches 114 form the active regions 104. The patterned photoresist layer may be removed during the etching process or using an additional process, such as an ashing process.

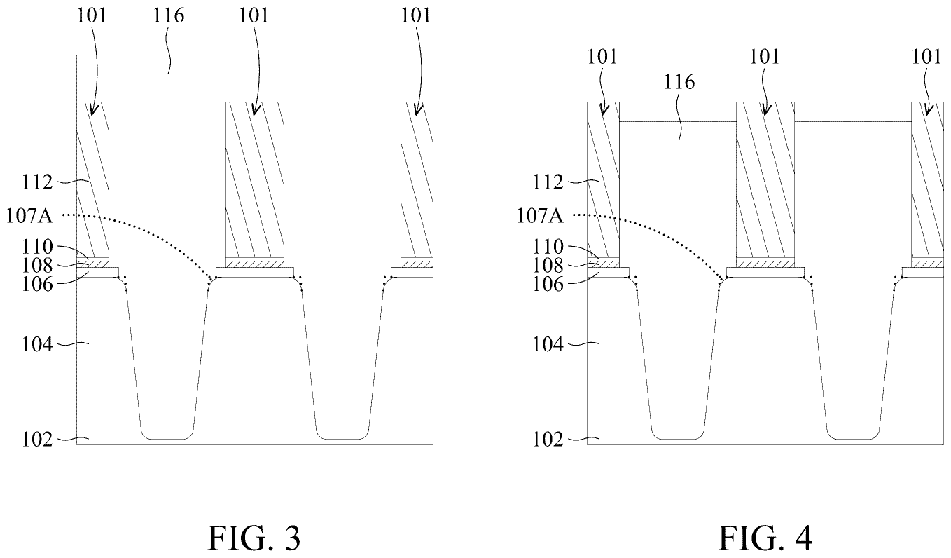

Referring to FIG. 3, a pull-back process is performed on the mask layer 112, the etch stop layer 110, the protection layer 108, and the pad oxide layer 106 of the strip patterns 101 such that the upper sidewalls of the strip patterns 101 to retract inward. The pull-back process may be a wet etching process that laterally etches the structure. In some embodiments, the wet etching process employs chemicals such as hot phosphoric acid and hydrofluoric acid solution. Subsequently, an isolation structure 116 is formed to overfill the trenches 114 and cover the strip patterns 101.

The isolation structure 116 may include multiple silicon oxide layers formed using different deposition techniques. For example, a high-aspect-ratio process (HARP) may be used to deposit a silicon oxide liner along the sidewalls and top surfaces of the strip patterns 101, followed by the depositing a spin-on glass (SOG) over the silicon oxide liner and overfilling the trenches 114. The spin-on glass undergoes an annealing process and is planarized using chemical mechanical polishing (CMP), then etched back to recess the spin-on glass, thereby forming the trenches between the strip patterns 101 again. Subsequently, a high-density plasma chemical vapor deposition (HDPCVD) process is used to deposit a silicon oxide layer over the spin-on glass and overfill the trenches.

Although FIG. 3 illustrates the boundary between the isolation structure 116 and the etch stop layer 110, as well as the boundary between the isolation structure 116 and the pad oxide layer 106, there may be no visible physical boundaries between these silicon oxide layers. Additionally, during the formation of the isolation structure 116, oxygen-containing gases (e.g., water vapor or oxygen) in the process atmosphere may oxidize the silicon of the active region 104, forming silicon oxide 107A. Specifically, portions of the active region 104 at its upper surface edges are oxidized and consumed. The silicon oxide 107A may also be referred to as a thickened portion 107A of the pad oxide layer 106.

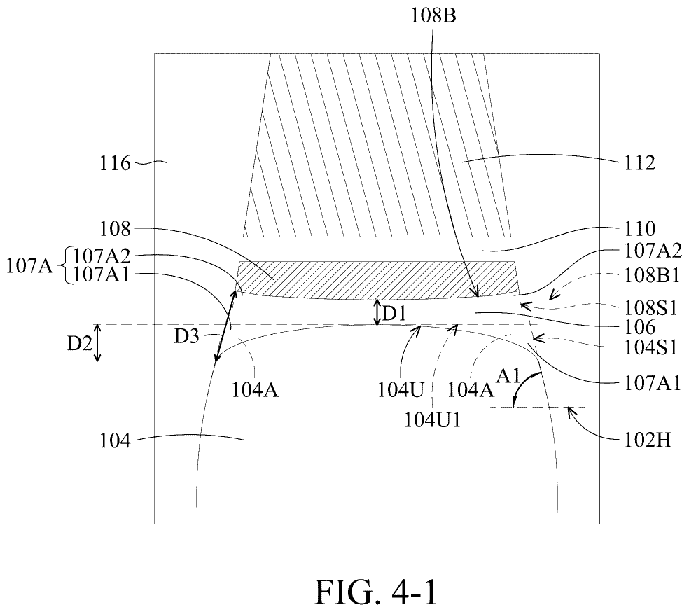

Referring to FIG. 4, the HDPCVD silicon oxide layer of the isolation structure 116 is planarized using CMP to expose the top surface of the mask layer 112. Next, an etching process is performed to recess the isolation structure 116, thereby partially exposing the sidewalls of the mask layer 112 of the strip patterns 101.

During the deposition of the high-density plasma chemical vapor deposition silicon oxide layer mentioned above, differences in process environments between deposition chambers may result in variations in the etching rate of the silicon oxide layer among different wafers. Therefore, nitrogen may be used in an annealing process between the CMP process and the etching process to reduce the etching rate variations of the silicon oxide layer among different wafers.

FIG. 4-1 illustrates some details of the profile of the pad oxide layer 106 profile in FIG. 4, in accordance with some embodiments of the present disclosure. During the formation of the isolation structure 116, oxygen-containing gases (e.g., water vapor or oxygen) in the process atmosphere may oxidize and consume portions 104A of the active region 104 at the edge of its upper surface 104U, resulting in the growth of the thickened portion (silicon oxide) 107A. The thickened portion 107A may include a first thickened portion 107A1 and a second thickened portion 107A2.

Due to the introduction of oxygen atoms, the total area of the thickened portions 107A1 and 107A2 is greater than the area of the consumed portion 104A of the active region 104. The thickened portion 107A may also be referred to as a bird beak feature. The growth of the thickened portion 107A causes the upper surface 104U of the active region 104 to exhibit an upward convex profile and raises both ends of the protection layer 108, resulting in a downward concave profile of the lower surface 108B of the protection layer 108.

The first thickened portion 107A1 is defined by the area enclosed by line 104U1, line 104S1, and the upper surface 104U of the active region 104. The line 104U1 is a horizontal line that is tangent to the highest point of the upper surface 104U of the active region 104 and parallel to the main surface of the semiconductor substrate 102. The line 104S1 is an extension line of the top portion of the sidewall of the active region 104. The top portion of the sidewall of the active region 104 (or line 104S1) intersects with a plane 102H that is parallel to the main surface of the semiconductor substrate 102 at an angle A1. The angle A1 is an acute angle ranging from about 60 degrees to about 90 degrees.

The second thickened portion 107A2 is defined by the area enclosed by line 108B1, line 108S1, and the lower surface 108B of the protection layer 108. The line 108B1 is a horizontal line that is tangent to the lowest point of the lower surface 108B of the protection layer 108 and parallel to the main surface of the semiconductor substrate 102. The line 108S1 is an extension line of the sidewall of the protection layer 108.

The central point (i.e., highest point) of the upper surface 104U of the active region 104 is separate from the central point (i.e., lowest point) of the lower surface 108B of the protection layer 108 by a distance D1. The distance D1 may be the shortest distance between the upper surface 104U and the lower surface 108B, which is also the minimum thickness of the pad oxide layer 106. The distance D1 is in a range from about 2.5 nm to about 15 nm. The edge (i.e., lowest point) of the upper surface 104U of the active region 104 is separate from the edge (i.e., highest point) of the lower surface 108B of the protection layer 108 by a distance D3. The distance D3 may be the longest distance between the upper surface 104U and the lower surface 108B. The distance D3 is in a range from about 4 nm to about 25 nm.

As measured along a direction perpendicular to the main surface of the semiconductor substrate 102, the dimension of the consumed portion 104A (or the first thickened portion 107A1) of the active region 104 has a maximum value (dimension D2) at the edge of the upper surface 104U and gradually decreases toward the central point of the upper surface 104U. Similarly, as measured along the vertical direction, the dimension of the second thickened portion 107A2 has a maximum value at the edge of the lower surface 108B and gradually decreases toward the central point of the lower surface 108B.

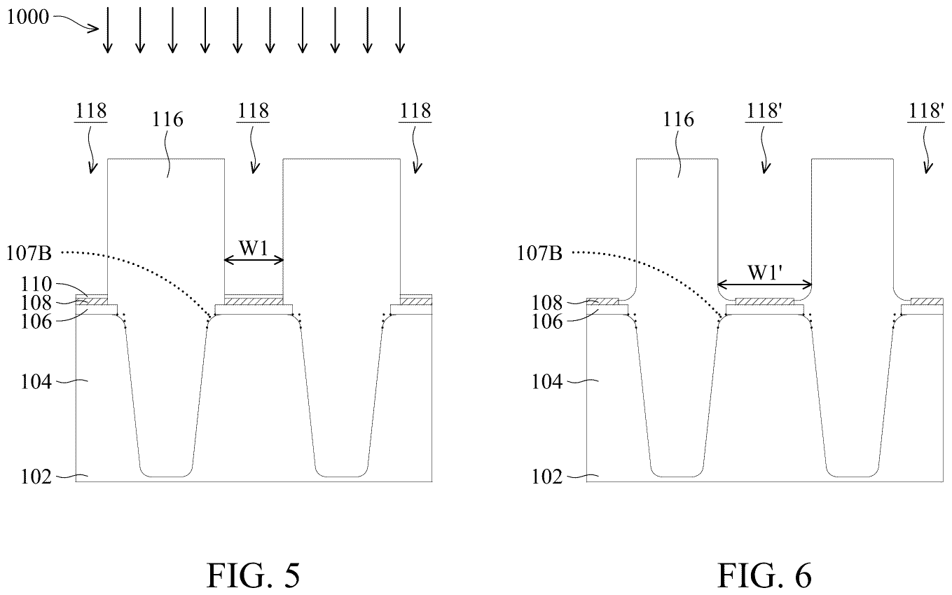

Referring to FIG. 5, an etching process (e.g., a wet etching process) is performed to remove the mask layers 112 of the strip patterns 101 thereby forming trenches 118 until the etch stop layers 110 of the strip patterns 101 are exposed. The width W1 of the trenches 118 ranges from about 20 nm to about 80 nm. Subsequently, an oxidation process 1000 is performed on the semiconductor structure to expand the thickened portion 107A. The oxidation process 1000 is used to precisely control the profile of the bird beak feature of the pad oxide layer 106. The thickened portion 107A undergoes further growth, and the grown thickened portion is denoted as 107B.

In some embodiments, the oxidation process 1000 is a rapid thermal oxidation (RTO) process. In some embodiments, the oxidation process 1000 may use an oxygen-containing gas (e.g., pure oxygen or a mixture of water vapor and oxygen) with a flow rate ranging from about 20 standard liters per minute (slm) to about 30 slm and is conducted at a temperature ranging from about 1000° C. to about 1150° C. for about 100 seconds to about 250 seconds. During the oxidation process 1000, the oxygen-containing gas is introduced into the trench 118, then diffuses through the isolation structure 116 and the edge of the pad oxide layer 106, reaching and oxidizing the active region 104. The formation of the thickened portion 107B at the edge of the upper surface of the active region 104 may help increase the thickness of the subsequently formed tunnel oxide at the edge of the active region, which may reduce the risk of data loss from the floating gate electrode layer at the edge of the upper surface of the active region. As a result, the low-temperature data retention issue of the resulting flash memory device is improved, thereby enhancing the reliability of the flash memory device.

In some cases where an oxidation process is performed using a furnace high-temperature processing before removing the mask layers of the strip patterns to form the bird beak feature, the diffusion path of the oxygen-containing gas in the isolation structure 116 is relatively long and is influenced by the remaining thickness of the mask layer. Consequently, the growth of the thickened portion is difficult to control precisely and may lead to excessive thermal punch-through, causing over-oxidation at the central portion of the active region. In the embodiments of the present disclosure, since the oxidation process 1000 is performed after the removal of the mask layer 112, the diffusion path of the oxygen-containing gas in the isolation structure 116 is shorter, and the aforementioned influence caused by the remaining thickness of the mask layer may not occur. Therefore, the thickened portion 107B can be precisely controlled to achieve the desired size and profile.

Furthermore, rapid thermal oxidation is performed on a single wafer at a time. Compared to furnace high-temperature processing, which processes multiple wafers simultaneously at a time, the size of the thickened portion 107B in the embodiments of the present disclosure exhibits better wafer-to-wafer (WtW) uniformity (i.e., smaller variation). Additionally, compared to furnace high-temperature processing, rapid thermal oxidation heats the wafer in a manner with a more uniform temperature distribution, resulting in improved within-wafer (WiW) uniformity of the thickened portion 107B in the embodiments of the present disclosure.

If the temperature of the oxidation process 1000 is too high and/or the duration is too long, the thickened portion 107B may grow excessively at the central portion of the upper surface of the active region 104, increasing the risk of thermal punch-through. If the temperature of the oxidation process 1000 is too low and/or the duration is too short, the thickened portion 107B may not grow sufficiently, which may not improve the low-temperature data retention issue.

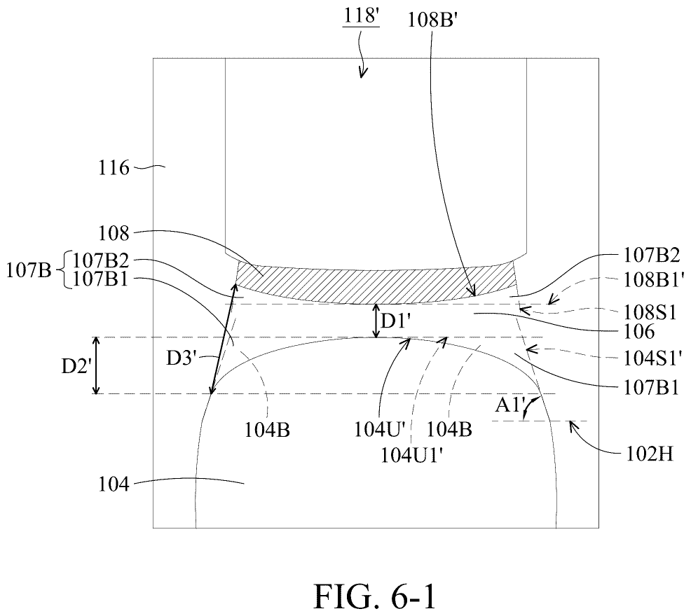

Referring to FIG. 6, an etching process (e.g., a wet etching process) is performed on the semiconductor structure in FIG. 5 to shrink the isolation structure 116, thereby laterally expanding the trench 118. The expanded trench 118 is denoted as 118′. The bottom critical dimension (BCD) W1′ of the trench 118′ ranges from about 30 nm to about 120 nm. If the bottom critical dimension W1′ is too large, the subsequent deposition process of the control gate electrode layer may become more challenging. If the bottom critical dimension W1′ is too small, the gate coupling ratio between the control gate electrode layer and the floating gate electrode layer is reduced, leading to a decrease in programming and erasing speeds. The etching process also removes the etch stop layer 110, thereby exposing the protection layer 108. The protection layer 108 can protect the pad oxide layer 106 and the thickened portion 107B during the etching process, preventing oxide loss.

In the absence of the etch stop layer 110 and the protection layer 108, the etching process would also partially remove the pad oxide layer 106. Consequently, the adjustment of the bottom critical dimension of the trench 118′ and the adjustment of the thickness of the pad oxide layer 106 (including the thickened portion 107B) would mutually influence each other, increasing the difficulty of obtaining a pad oxide layer 106 with the desired profile. Therefore, in the embodiments of the present disclosure, by forming the strip pattern with the etch stop layer 110 and the protection layer 108, the expansion of the trench 118 and the profile of the pad oxide layer 106 can be independently controlled. Additionally, in cases where furnace high-temperature processing is used and causes excessive oxidation at the central portion of the active region, the amount of etching required to shrink the isolation structure must be increased. This not only leads to an excessive expansion of the bottom critical dimension of the trench but also results in excessively thinning down the pad oxide layer at the edge of the upper surface of the active region.

Although FIG. 6 shows that the sidewalls of the protection layer 108 are partially exposed from the trench 118′, in some embodiments, the sidewalls of the protection layer 108 may remain completely covered by the isolation structure 116, depending on the amount of etching performed to shrink the isolation structure.

FIG. 6-1 illustrates some details of the profile of the pad oxide layer 106 in FIG. 6, in accordance with some embodiments of the present disclosure. During the oxidation process 1000, the oxygen-containing gas in the process atmosphere consumes a portion 104B at the edge of the upper surface 104U′ of the active region 104, resulting in further growth of the thickened portion (silicon oxide) 107A. The newly grown thickened portion is denoted as 107B. The thickened portion 107B may include a first thickened portion 107B1 and a second thickened portion 107B2.

Since the oxidation process 1000 further consumes the active region 104, the upper surface 104U′ may exhibit a more steeply convex profile than the upper surface 104U (shown in FIG. 4-1), and the rise of both ends of the protection layer 108 becomes more obvious, making the lower surface 108B′ of the protection layer 108 have a more steeply convex profile than the lower surface 108B (shown in FIG. 4-1). For example, the radius of curvature at the central point of the upper surface 104U′ may be smaller than that of the upper surface 104U, and the radius of curvature at the central point of the lower surface 108B′ may be smaller than that of the lower surface 108B.

The first thickened portion 107B1 is defined by the area enclosed by line 104U1′, line 104S1′, and the upper surface 104U′ of the active region 104. The line 104U1′ is a horizontal line that is parallel to the main surface of the semiconductor substrate 102 and is tangent to the highest point of the upper surface 104U′ of the active region 104. The line 104S1′ is an extension line of the upper portion of the sidewall of the active region 104. After the oxidation process 1000, the upper portion of the sidewall of the active region 104 (or line 104S1′) intersects the plane 102H, which is parallel to the main surface of the semiconductor substrate 102, at an angle A1′. The angle A1′ may be equal to or smaller than the angle A1. The angle A1′ is an acute angle in the range from about 60 degrees to about 90 degrees. The area of the first thickened portion 107B1 is larger than that of the first thickened portion 107A1.

The second thickened portion 107B2 is defined by the area enclosed by line 108B1′, line 108S1, and the lower surface 108B′ of the protection layer 108. The line 108B1′ is a horizontal line that is parallel to the main surface of the semiconductor substrate 102 and is tangent to the lowest point of the lower surface 108B′ of the protection layer 108. The area of the second thickened portion 107B2 is larger than that of the second thickened portion 107A2.

A distance D1′ is present between the central (i.e., the highest point) of the upper surface 104U′ of the active region 104 and the central (i.e., the lowest point) of the lower surface 108B′ of the protection layer 108. The distance D1′ may be the shortest distance between the upper surface 104U′ and the lower surface 108B′, which is also the minimum thickness of the pad oxide layer 106. The distance D1′ is in a range from about 2.5 nm to about 20 nm. The edge of the upper surface 104U′ of the active region 104 is separate a distance D3′ from the edge of the lower surface 108B′ of the protection layer 108. The Distance D3′ may be the longest distance between the upper surface 104U′ and the lower surface 108B′. The distance D3′ is in a range from about 6 nm to about 50 nm.

The distance D1′ may be equal to or greater than the distance D1. The ratio of the distance D1′ to the distance D1 (D1′/D1) ranges from 1 to about 1.3. The Distance D3′ is greater than the distance D3. The ratio of the distance D3′ to the distance D3 (D3′/D3) ranges from 1.5 to about 2. The ratio (D1′/D1) is smaller than the ratio (D3′/D3). In other words, during the oxidation process 1000, the thickened portion 107B of the pad oxide is controlled at the edge portion of the upper surface 104U of the active region 104, while the central portion of the upper surface 104U remains substantially unoxidized or undergoes only minor oxidation.

As measured along a direction perpendicular to the main surface of the semiconductor substrate 102, the consumed portion 104B (or the first thickened portion 107B1) of the active region 104 has a maximum dimension (dimension D2′) at the edge of the upper surface 104U′ and gradually decreases toward the central point of the upper surface 104U′. The maximum dimension D2′ is greater than the maximum dimension D2. Similarly, as measured along the vertical direction, the dimension of the second thickened portion 107B2 has a maximum size at the edge of the lower surface 108B′ and gradually decreases toward the central point of the lower surface 108B′. The maximum dimension of the thickened portion 107B2 is greater than that of the thickened portion 107A2. The profile of the thickened portion 107B can be adjusted by modifying the parameters of a rapid thermal oxidation process, such as temperature and/or duration.

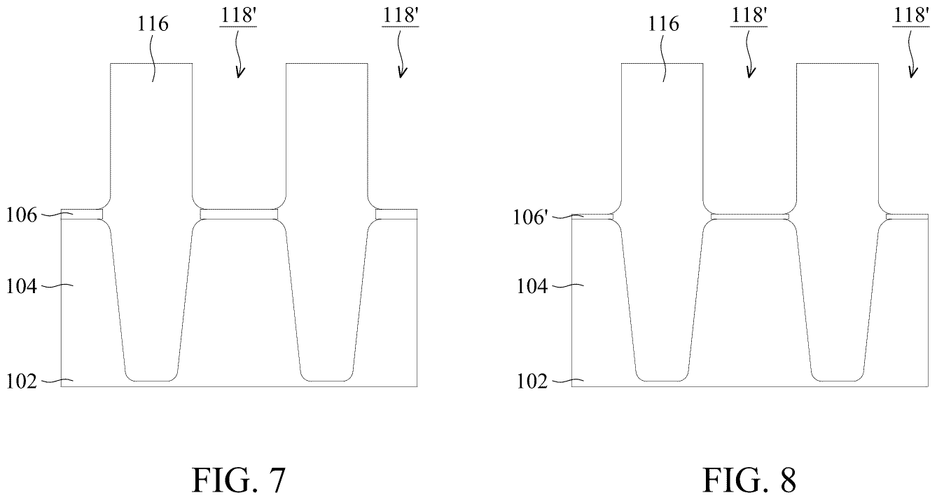

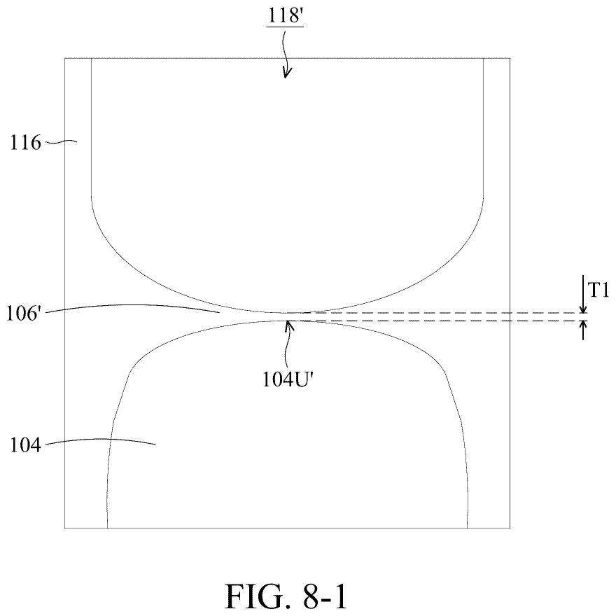

Referring to FIG. 7, an etching process (e.g., a wet etching process) is used to remove the protection layers 108 of the strip patterns 101 until the pad oxide layer 106 is exposed. Then, referring to FIG. 8, a cleaning process (e.g., a wet etching process) is used to recess the pad oxide layer 106. The recessed pad oxide layer 106 is labeled as 106′.

FIG. 8-1 illustrates some details of the profile of the pad oxide layer 106′ in FIG. 8, in accordance with some embodiments of the present disclosure. The pad oxide layer 106′ has a thickness T1 at the central point of the upper surface 104U′, where the thickness T1 is the minimum thickness of the pad oxide layer 106′. The thickness T1 is in a range from about 0.6 nm to about 3 nm. If thickness T1 is too small or approaches zero, the uniformity of the subsequently formed tunnel oxide may deteriorate, and the pad oxide layer 106′ at the edge of the active region 104 may be excessively lost. If the thickness T1 is too large, the quality of the subsequently formed tunnel oxide may be degraded, and the pad oxide layer 106′ may remain too much at the edge of the active region 104, which may negatively affect the performance of the resulting flash memory device.

In cases where the oxidation process is performed using a furnace high-temperature processing, the pad oxide layer tends to have a greater thickness at the central portion of the upper surface. Therefore, when the cleaning process thins down the pad oxide layer to have the thickness T1, the pad oxide layer at the edge of the active region may become too thin. In accordance with embodiments of the present disclosure, since the pad oxide layer 106 has a smaller thickness at the central point of the upper surface 104U′ (i.e., distance D1′), the pad oxide layer 106′ at the edge of the active region remains relatively thick when the cleaning process thin down the pad oxide layer 106′ to have the thickness T1.

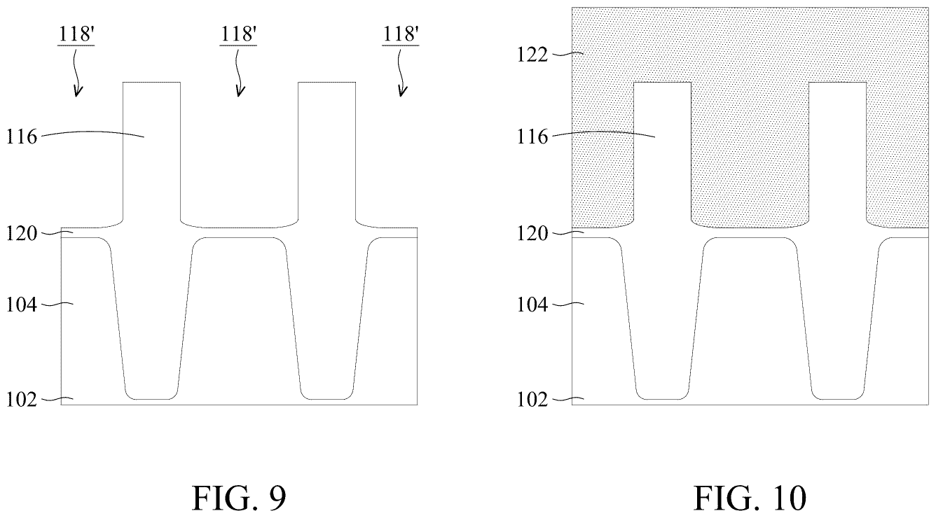

Referring to FIG. 9, a tunnel oxide layer 120 is formed on the upper surface of the active region 104 using an in-situ steam generation (ISSG) process. During the in-situ steam generation process, oxygen-containing gases (e.g., water vapor or oxygen) in the process atmosphere oxidize the silicon from the active region 104 to form silicon oxide. Consequently, the thickness of the pad oxide layer 106 increases, and the grown oxide layer 106, along with the thickened portion 107B, collectively functions as the tunnel oxide layer 120.

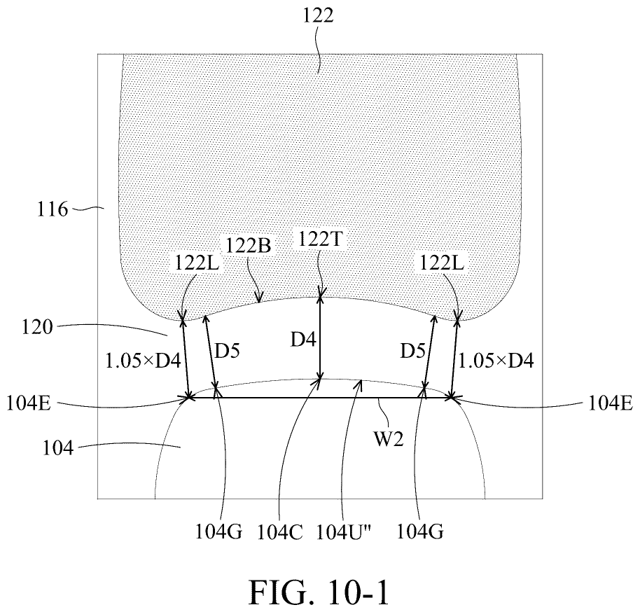

Referring to FIG. 10, floating gate electrode layers 122 are formed to fill the trench 118′ and cover the isolation structure 116. The floating gate electrode layers 122 are made of an electrically conductive material, such as polysilicon, amorphous silicon, or a combination thereof, and/or other conductive materials. The floating gate electrode layers 122 may be deposited using a CVD process.

FIG. 10-1 illustrates some details of the profile of the tunnel oxide layer 120 in FIG. 10, in accordance with some embodiments of the present disclosure. Because the pad oxide layer 106′ has a profile that is thin at the central point and thick at the edges, during the in-situ steam generation (ISSG) process, the portion of the active region 104 near the central point of the upper surface 104U′ experiences a greater degree of oxidation and consumption, whereas the portion of the active region near the edges of the upper surface 104U′ undergoes a lower degree of oxidation and consumption. As a result, after the ISSG process, the upper surface 104U″ of the active region 104 may have a smoother convex profile compared to the upper surface 104U′ (shown in FIG. 8-1).

The lower surface 122B of the floating gate electrode layer 122 (or the upper surface of the tunnel oxide layer 120) may have a wavy profile. Specifically, the lower surface 122B has two lowest points 122L near its edges and one highest point 122T at its central point.

The minimum distance measured from the central point 104C of the upper surface 104U″ of the active region 104 to the lower surface 122B of the floating gate electrode layer 122 is defined as the bulk distance D4. The bulk distance D4 is in a range from about 8 nm to about 16 nm.

The edge 104E of the upper surface 104U″ of the active region 104 is defined as a point on the upper surface 104U″ where the minimum distance between the point and the lower surface 122B satisfies 1.05 times the bulk distance D4. The width W2 between the two edges 104E is defined as the effective channel width of the active region 104. The width W2 positively influences the on-state current of the resulting flash memory device.

In the embodiments of the present disclosure, because the lower surface 122B of the floating gate electrode layer 122 has two lowest points 122L near its edges, the edges 104E of the upper surface 104U″ of the active region 104 can be positioned further away from the central point 104C of the upper surface 104U″. As a result, the active region 104 can have a larger effective channel width W2, thereby enhancing the operating current of the resulting flash memory device. In some embodiments, the ratio of the width W2 to the nominal critical dimension of the active region can be greater than 95%, such as greater than 98%.

The distance D5 is the shortest distance between the upper surface 104U″ and the lower surface 122B (i.e., the minimum thickness of the tunnel oxide layer 120). The terminal of the distance D5 on the upper surface 104U″ of the active region 104 is referred to as the corner point 104G. The corner point 104G is located between the central point 104C and the edge 104E. The shortest distance D5 is in a range from 7 nm to about 14 nm. In some embodiments, the distance between the upper surface 104U″ and the lower surface 122B gradually decreases from the central point 104C to the corner point 104G and gradually increases from the corner point 104G to the edge 104E. The central point 104C is positioned higher than the corner point 104G, and the corner point 104G is positioned higher than the edge 104E.

If the ratio of the shortest distance D5 to the bulk distance D4 (D5/D4), also referred to as the corner ratio, is too low, the risk of data loss stored in the floating gate electrode layer due to leakage from the upper surface of the active region increases. In accordance with embodiments of the present disclosure, since the pad oxide layer 106′ retains a relatively large thickness at the edge of the upper surface of the active region, the tunnel oxide layer 120 at the corner point 104G (i.e., the location where the tunnel oxide layer 120 is thinnest) can have a greater thickness compared to existing techniques, thereby increasing the corner ratio (D5/D4). As a result, the low-temperature data retention performance of the resulting flash memory device is improved. In some embodiments, the corner ratio (D5/D4) can be greater than 90%, for example, greater than 95%.

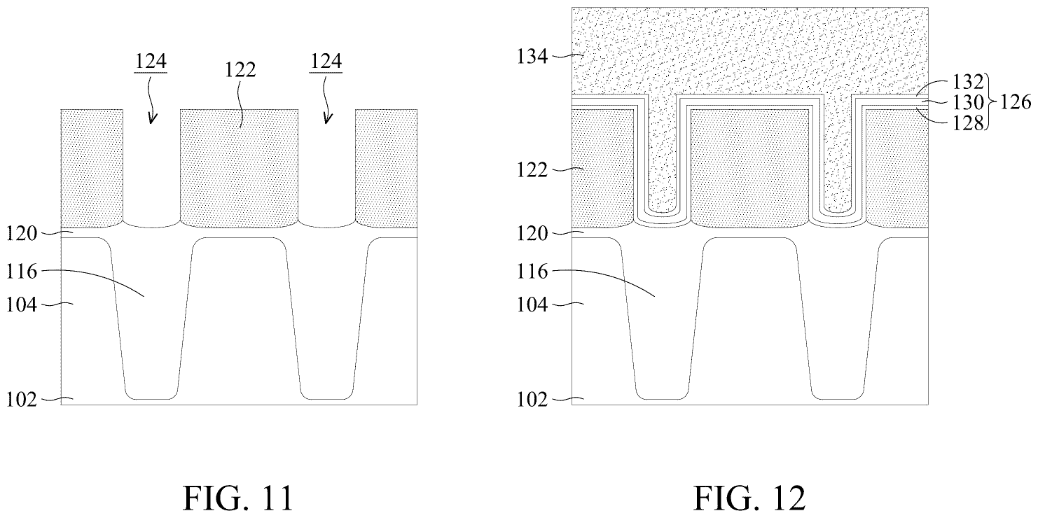

Referring to FIG. 11, the floating gate electrode layer 122 is planarized using CMP to expose the upper surface of the isolation structure 116. Next, an etching process (e.g., a wet etching process) is used to recess the isolation structure 116, thereby forming trenches 124 that expose the sidewalls of the floating gate electrode layer 122. Referring to FIG. 12, an inter-gate dielectric structure 126 is formed along the upper surface and sidewalls of the floating gate electrode layer 122 and the upper surface of the isolation structure 116, thereby partially filling the trenches 124. Subsequently, control gate electrode layers 134 are formed over the inter-gate dielectric structure 126, thereby overfilling the trenches 124 to obtain the flash memory device.

The inter-gate dielectric structure 126 may be a tri-layer structure comprising an oxide layer 128, a nitride layer 130, and an oxide layer 132. The control gate electrode layers 134 are made of a conductive material such as polysilicon, amorphous silicon, or a combination thereof, and/or other conductive materials. The inter-gate dielectric structure 126 and the control gate electrode layers 134 may be deposited using chemical vapor deposition (CVD). The steps described in FIGS. 11 and 12 do not affect the profiles of the upper surfaces 104U″ of the active regions 104 or the lower surfaces 122B of the floating gate electrode layers 122, and thus the details of the profile of the tunnel oxide layer 120 in FIG. 12 are as described above in FIG. 10-1, and are not repeated again.

As described above, the embodiments of the present disclosure provide a flash memory and a method for forming the same. After removing the silicon nitride mask layer of the strip pattern, a rapid thermal oxidation process is used to form the thickened portion of the pad oxide layer at the edge of the active region. The well-controlled oxidation process may prevent the active region from suffering excessive thermal punch-through and allow the pad oxide layer to have the desired bird's beak feature. Therefore, the low-temperature data retention issue of the flash memory device may be improved, and the operating current of the flash memory device may be increased.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a flash memory, comprising:
forming a strip pattern, which includes an active region, a pad oxide layer, a protection layer, an etch stop layer, and a mask layer sequentially stacked over a semiconductor substrate, wherein sidewalls of the strip pattern are exposed from first trenches;
forming an isolation structure in the first trenches;
etching the mask layer of the strip pattern to form a second trench until the etch stop layer is exposed;
performing an oxidation process on the active region;
removing the etch stop layer;
removing the protection layer; and
forming a first gate electrode layer in the second trench.

2. The method for forming the flash memory as claimed in claim 1, wherein the oxidation process is a rapid thermal oxidation process.

3. The method for forming the flash memory as claimed in claim 1, wherein the protection layer is made of a nitride, and the mask layer is made of a nitride.

4. The method for forming the flash memory as claimed in claim 1, wherein performing the oxidation process on the active region comprises:
consuming a portion of the active region, wherein the consumed portion of the active region is oxidized to form a thickened portion of the pad oxide layer.

5. The method for forming the flash memory as claimed in claim 4, wherein as measured in a vertical direction, a dimension of the consumed portion of the active 2 region gradually decreases from an edge of an upper surface of the active region toward a central point of the upper surface of the active region.

6. The method for forming the flash memory as claimed in claim 4, wherein the thickened portion raises both ends of the protection layer.

7. The method for forming the flash memory as claimed in claim 1, wherein the etch stop layer is made of an oxide or an oxynitride.

8. The method for forming the flash memory as claimed in claim 1, further comprising:
expanding the second trench while removing the etch stop layer.

9. The method for forming the flash memory as claimed in claim 1, further comprising, before forming the first gate electrode layer in the second trench:
recessing the pad oxide layer; and
thickening the pad oxide layer to form a tunnel oxide layer.

10. The method for forming the flash memory as claimed in claim 1, further comprising:
removing an upper portion of the isolation structure to form third trenches that expose the first gate electrode layer;
forming an inter-gate dielectric structure along the first gate electrode layer; and
forming a second gate electrode layer in the third trenches.

11. A method for forming a flash memory, comprising:
forming a strip pattern over a semiconductor substrate, wherein the strip pattern includes an active region, a pad oxide layer over the active region, and a mask layer over the pad oxide layer;
forming an isolation structure surrounding the strip pattern;
removing the mask layer of the strip pattern to form a first trench;
performing a rapid thermal oxidation process, which comprises:
introducing an oxygen-containing gas into the first trench;
diffusing the oxygen-containing gas through the isolation structure to the active region; and
oxidizing a portion of the active region;
forming a first gate electrode layer in the first trench;
recessing the isolation structure; and
forming an inter-gate dielectric structure and a second gate electrode layer over the isolation structure to surround the first gate electrode layer.

12. The method for forming the flash memory as claimed in claim 11, wherein the rapid thermal oxidation process uses an oxygen-containing gas which includes pure oxygen or a mixture of water vapor and oxygen.

13. The method for forming the flash memory as claimed in claim 11, wherein the rapid thermal oxidation process is performed at a temperature ranging from about 1000° C. to about 1150° C. for a duration ranging from about 100 seconds to about 250 seconds.

14. The method for forming the flash memory as claimed in claim 11, wherein the strip pattern further includes a protection layer over the pad oxide layer and an etch stop layer between the protection layer and the mask layer.

15. The method for forming the flash memory as claimed in claim 14, wherein removing the mask layer of the strip pattern comprises etching the mask layer until the etch stop layer is exposed from the first trench.

16. The method for forming the flash memory as claimed in claim 14, further comprising:
etching the isolation structure and the etch stop layer of the strip pattern, wherein the protection layer of the strip pattern protects the pad oxide layer of the strip pattern from being recessed; and
removing the protection layer.

17. The method for forming the flash memory as claimed in claim 11, wherein:
before the rapid thermal oxidation process, a central point of an upper surface of the active region is separate from a central point of a lower surface of the protection layer by a first distance, and an edge of the upper surface of the active region is separate from an edge of the lower surface of the protection layer by a second distance,
after the rapid thermal oxidation process, the central point of the upper surface of the active region is separate from the central point of the lower surface of the protection layer by a third distance, and the edge of the upper surface of the active region is separate from the edge of the lower surface of the protection layer by a fourth distance, and
a first ratio of the third distance to the first distance is smaller than a second ratio of the fourth distance to the second distance.

18. The method for forming the flash memory as claimed in claim 11, further comprising, before forming the first gate electrode layer in the first trench:
recessing the pad oxide layer; and
forming a tunneling oxide layer over the active region using an in-situ steam generation process.

19. The method for forming the flash memory as claimed in claim 18, wherein an upper surface of the tunneling oxide layer has a first lowest point, a second lowest point, and a highest point located between the first lowest point and the second lowest point.

20. The method for forming the flash memory as claimed in claim 11, wherein as measured in a vertical direction, the oxidized portion of the active region has a dimension that decreases from an edge of an upper surface of the active region toward a central point of the upper surface of the active region.
